(19) United States
(12) Patent Application Publication
(10) Pub. No.: US 2009/0121300 A1
(43) Pub. Date: May 14, 2009

(54) MICROELECTRONIC IMAGER PACKAGES AND ASSOCIATED METHODS OF PACKAGING

(75) Inventor: James L. Voelz, Meridian, ID (US)

Correspondence Address: PERKINS COIE LLP;PATENT-SEA, PO BOX 1247, SEATTLE, WA, 98111-1247, US

(73) Assignee: Micron Technology, Inc., Boise, ID (US)

(21) Appl. No.: 11/940,184

(22) Filed: Nov. 14, 2007

(51) Int. Cl. H01L 31/0203

(52) U.S. Cl. 257/432; 438/65; 257/E31.001

(57) ABSTRACT

The microelectronic imager packages include a semiconductor die having a plurality of photo sensors, a cover spaced apart from the semiconductor die and facing the photo sensors, and a coupling structure between the semiconductor die and the cover. The coupling structure has a spacer separating the semiconductor die and the cover and an adhesive proximate to the spacer. The adhesive bonds the spacer, the semiconductor die, and the cover together.

### TECHNICAL FIELD

The present disclosure is directed to microelectronic imager packages and methods for manufacturing such microelectronic imager packages.

### BACKGROUND

Individually packaged microelectronic imagers are widely used today in digital cameras, camcorders, and other imaging equipment. FIG. 1 is a cross-sectional view of a typical microelectronic imager package 10 in accordance with the prior art. As shown in FIG. 1, the package 10 includes a semiconductor die 11 spaced apart from and bonded to a transparent cover 12 by a coupling structure 15. The die 11 includes photo sensors 18 formed in and/or on a substrate 13 and corresponding microlenses 20. The coupling structure 15 includes a spacer 14 (e.g., formed from a photoresist) deposited on the cover 12 and an adhesive 16 adhering the spacer 14 to the die 11.

One drawback of the package 10 is that the coupling structure 15 may be inadequate in securing the die 11 and the cover 12 together when the package 10 is under mechanical and/or thermal stress. As a result, the die 11 and the cover 12 can separate from one another and cause the package to fail. Accordingly, several improvements for enhancing the structural integrity of the package 10 would be desirable.

### BRIEF DESCRIPTION OF THE DRAWINGS

FIG. 1 is a partially schematic cross-sectional view of a microelectronic imager in accordance with the prior art.

FIG. 2A is a partially schematic cross-sectional view of the microelectronic imager package in accordance with an embodiment of the disclosure.

FIG. 2B is a partially schematic top view of the microelectronic imager package in FIG. 2A in accordance with an embodiment of the disclosure.

FIGS. 3A-D are partially schematic cross-sectional views of a portion of the microelectronic imager package of FIG. 2A in accordance with several embodiments of the disclosure.

FIGS. 4A and 4B are partially schematic top views of microelectronic imager packages in accordance with embodiments of the disclosure.

FIGS. 5A-D illustrate a process for forming the microelectronic imager package shown in FIG. 2A-B or 4A-B in accordance with an embodiment of the disclosure.

FIG. 6 is a schematic diagram of a system that can include one or more microelectronic imager packages in accordance with embodiments of the disclosure.

### DETAILED DESCRIPTION

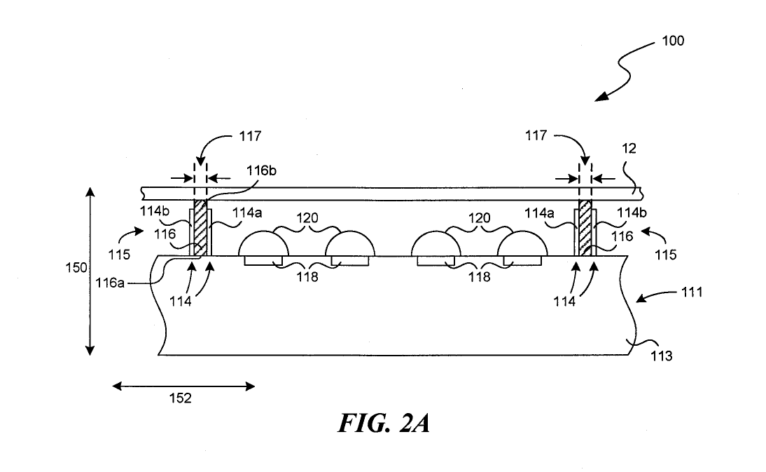

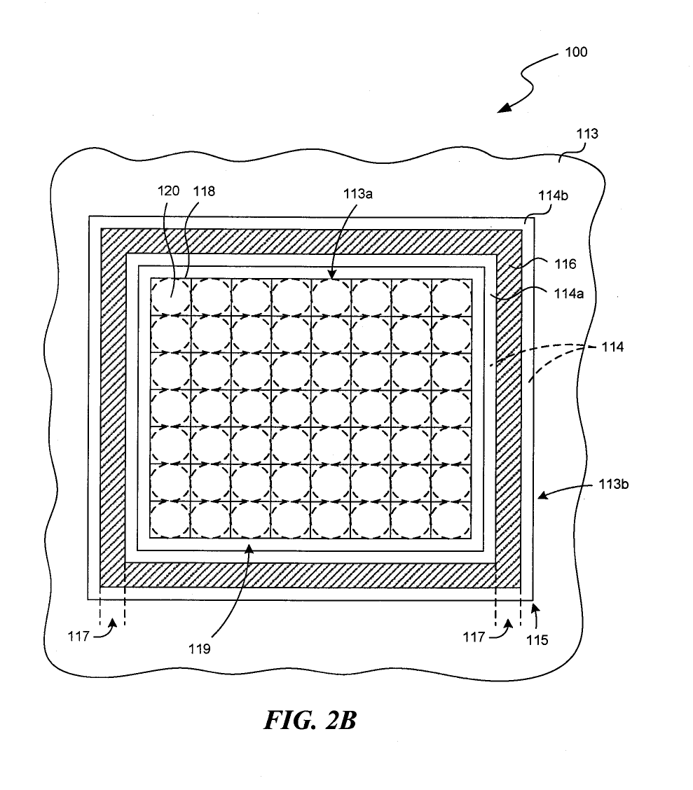

Specific details of several embodiments of the disclosure are described below with reference to microelectronic imager packages and methods for manufacturing microelectronic imager packages from semiconductor components. The semiconductor components are manufactured on semiconductor wafers that can include substrates upon which and/or in which microelectronic devices, micromechanical devices, data storage members, optics, read/write components, and other features are fabricated. For example, SRAM, DRAM (e.g., DDR/SDRAM), flash-memory (e.g., NAND flash-memory), processors, CMOS and/or CCD imagers, and other types of devices can be constructed on semiconductor wafers. Although many of the embodiments are described below with respect to semiconductor devices that have integrated circuits, other embodiments include other types of devices manufactured on other types of substrate. Moreover, several other embodiments of the invention can have different configurations, components, or procedures than those described in this section. A person of ordinary skill in the art, therefore, will accordingly understand that the invention can have other embodiments with additional members, or the invention can have other embodiments without several of the features shown and described below with reference to FIGS. 2-5B.

FIG. 2A is a partially schematic cross-sectional view of a microelectronic imager package 100 in accordance with an embodiment of the disclosure. As shown in FIG. 2A, the package 100 can include a semiconductor die 111, a cover 112 spaced apart from the die 111, and a coupling structure 115 that bonds the die 111 and the cover 112 together. In the illustrated embodiment, the die 111 includes at least one CMOS imager that has a semiconductor substrate 113, a plurality of photo sensors 118 (e.g., photodiodes, photogates, etc.) formed in and/or on the substrate 113, and a plurality of microlenses 120 on a top surface of the substrate 113. Individual microlenses 120 correspond to one of the photo sensors 118. In other embodiments, the die 111 can also include a CCD imager and/or other types of imagers. The cover 112 can be a glass plate, a polymer plate, and/or other suitable component transmissive to the desired spectrum of radiation.

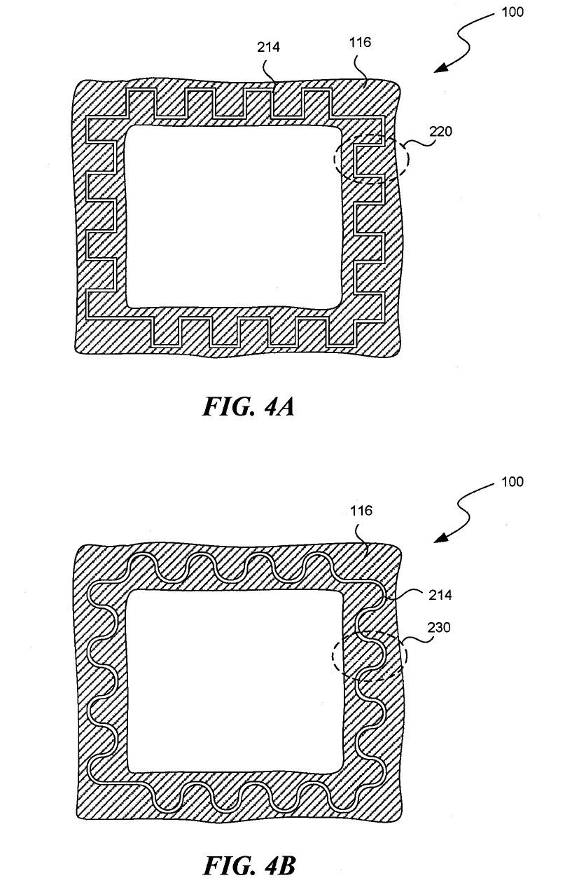

The coupling structure 115 can include a spacer 114 separating the die 111 from the cover 112 and an adhesive 116 bonding the spacer 114, the die 111, and the cover 112 together. The spacer 114 can include a dam, a post, and/or other suitable structure projecting away from the die 111 toward the cover 112 in a first direction 150. For example, in the illustrated embodiment, the spacer 114 includes first and second dam portions 114a-b that are spaced apart from one another by a gap 117 along a second direction 152 to define a channel between the dam portions 114a-b. The first and second directions 150, 152 are generally perpendicular to one another. In other embodiments, the spacer 114 can be a unitary U-shaped channel and/or have other configurations, several of which are described in more detail below with reference to FIGS. 4A and 4B. The spacer 114 can be formed from a photoresist, a polymer, and/or other materials with sufficient structural strength.

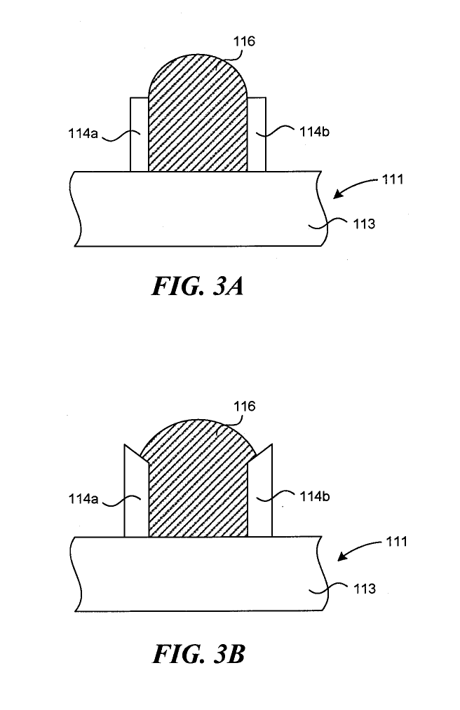

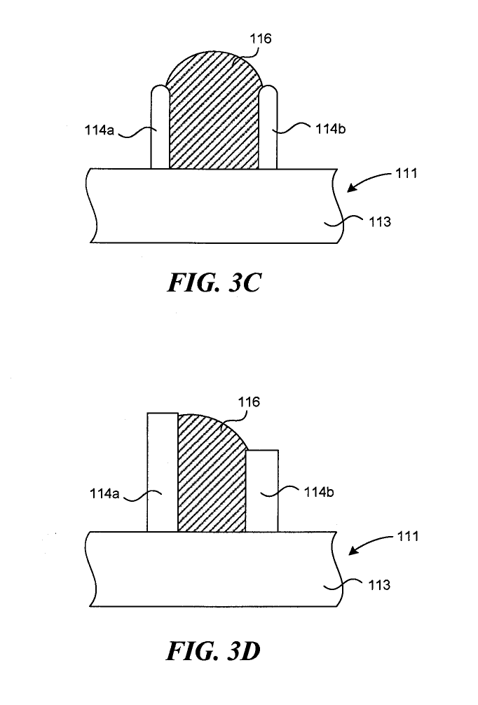

In certain embodiments, the adhesive 116 can include a UV curable epoxy and/or other suitable adhesive material positioned at least partially in the gap 117. As shown in FIG. 2A, the adhesive 116 substantially fills the gap 117 and extends from a first end 116a that contacts the die 111 to a second end 116b that contacts the cover 112. The adhesive 116 also contacts the side surfaces of the first and second dam portions 114a-b of the spacer 114 along substantially the entire length of the spacer 114. Even though the second end 116b of the adhesive 116 shown in FIG. 2A extends beyond the spacer 114, in other embodiments, the second end 116b of the adhesive 116 can be generally flush with the top of the spacer 114. In these embodiments, the height of the spacer 114 is at least approximately the same as the distance between the die 111 and the cover 112. In further embodiments, the adhesive 116 can be positioned approximate to the spacer 114 but at least partially outside of the gap 117. Details of various embodiments of the coupling structure 115 are described below with reference to FIGS. 3A-D, 4A, and 4B.

FIG. 2B is a partially schematic top view of an embodiment of the microelectronic imager package 100 in FIG. 2A in which the cover 112 is not shown. As shown in FIG. 2B, the photo sensors 118 and the microlenses 120 can be arranged into an array 119 and positioned at a central region 113a of the substrate 113. The first and second dam portions 114a-b of this embodiment are rectilinear walls positioned around a periphery 113b of the substrate 113. The gap 117 separates the first dam portion 114a from the second dam portion 114b around substantially the entire perimeter of the array 119.

FIGS. 3A-D are partially schematic and enlarged cross-sectional views of different embodiments of the coupling structure 115 in FIG. 2A. As shown in FIGS. 3A-D, the spacer 114 of the coupling structure 115 can have various cross-sectional shapes. For example, the first and/or second dam portions 114a-b of the spacer 114 can have a generally rectangular cross-sectional shape as shown in FIG. 3A. As shown in FIG. 3B, the first and/or second dam portions 114a-b can alternatively have a tapered end that helps to contain the adhesive 116 during assembly. Any of the foregoing embodiments of the first and/or second dam portions 114a-b can also have a cross-sectional shape with a rounded end as shown in FIG. 3C. In any of the embodiments discussed above, the first and second dam portions 114a-b have generally the same length. However, in certain embodiments, the first and second dam portions 114a-b can have different lengths as shown in FIG. 3D. In further embodiments, one of the first and second dam portions 114a-b can be omitted.

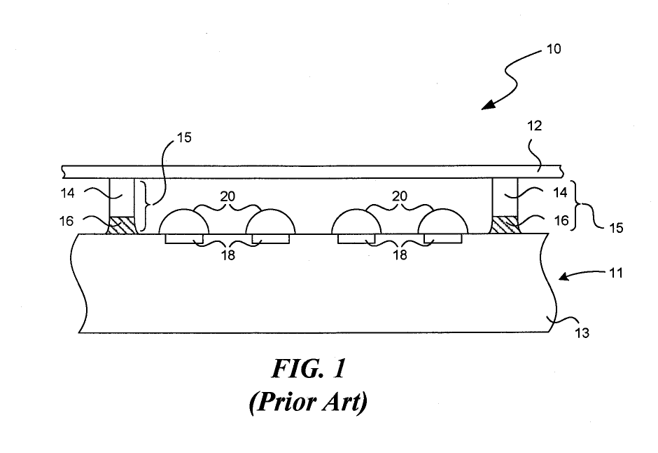

Several embodiments of the coupling structure 115 can improve the structural integrity of the microelectronic imager package 100. The inventor has recognized that the structural weakness of conventional imager packages is at least partially due to insufficient bonding between the package components. For example, in the microelectronic imager package 10 of FIG. 1, the inventor has discovered that the die 11 and the cover 12 tend to separate from one another at the junction between the spacer 14 and the cover 12. Thus, adhering the spacer 114 and the cover 112 together with the adhesive 116 can increase the bonding strength between (a) the spacer 114 and the cover 112 and (b) between the spacer 114 the die 111. As a result, the microelectronic imager package 100 can have improved structural integrity.

The coupling structure 115 shown in FIGS. 2A and 2B has a generally rectangular shape around the perimeter of the array 119, in other embodiments the coupling structure 115 can have a generally circular shape, an oval shape, and/or other suitable shapes. In further embodiments, the spacer 114 of the coupling structure 115 can be non-continuous along at least a portion of the perimeter of the photo sensor array 119. For example, in certain embodiments, the spacer 114 can include at least three posts (not shown) spaced apart along the perimeter of the array 119 with the adhesive 116 extending between each pair of the posts.

Instead of having the spacer 114 with two separate dam portions 114a-b, in certain embodiments the package 110 can also include a unitary spacer 214. FIGS. 4A and 4B are partially schematic top views of different embodiments of a spacer 214 for use with the microelectronic imager package 100. The cover 112, the photo sensors 118, and the microlenses 120 are not shown in FIGS. 4A and 4B for clarity. As shown in FIGS. 4A and 4B, the spacer 214 can be unitary and non-linear along at least a portion of its perimeter. In the embodiment shown in FIG. 4A, the spacer 214 can have a plurality of sections 220 arranged in series to form a castlated or square serpentine-like structure. The adhesive 116 can be proximate to and at least partially in contact with the sections 220 around the perimeter of the spacer 214. In another embodiment shown in FIG. 4B, the spacer 214 can also include a plurality of curved sections 230 arranged in series to form a serpentine structure. In other embodiments, the spacer 214 can be triangular, trapezoidal, semicircular, and/or other suitably shaped sections. In the embodiments shown in FIGS. 4A and 4B, the adhesive 116 generally surround the spacer 214 by contacting both the inward-facing and outward-facing side surfaces of the spacer 214. In further embodiments, the adhesive 116 can be in contact with only one of the side surfaces of the spacer 214.

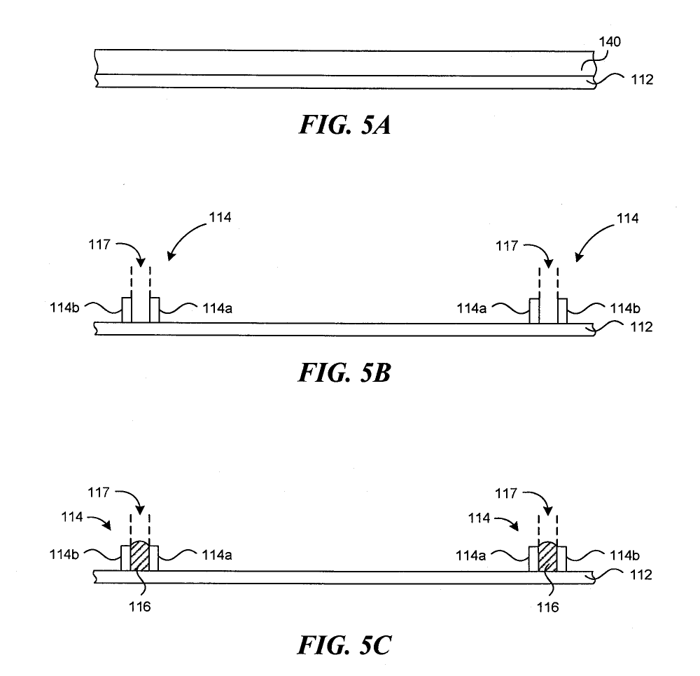

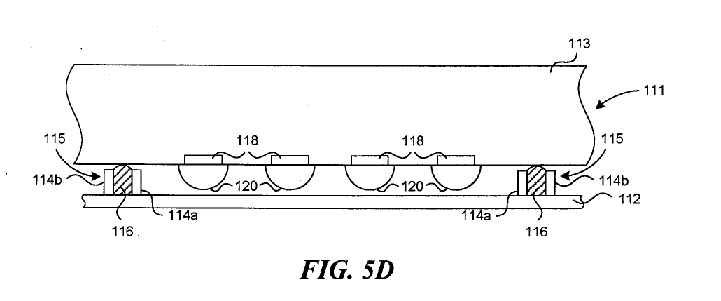

FIGS. 5A-D illustrate stages of an embodiment of a process for forming the microelectronic imager package 100. FIG. 5A illustrates an early stage of the process that includes depositing a photoresist layer 140 onto the cover 112. FIG. 5B illustrates a subsequent stage of the process that includes patterning and etching the deposited photoresist layer 140 to form a spacer. In the illustrated embodiment, the photoresist layer 140 is etched to form the spacer 114 with the first and second dam portions 114a-b spaced apart by the gap 117 as shown in FIGS. 2A-B. However, one skilled in the art will appreciate that the photoresist layer 140 can also be patterned and etched to form the spacer 214 as shown in FIGS. 4A and 4B or a spacer with other desired configurations.

Another stage of the process includes depositing the adhesive 116 onto the cover 112. In one embodiment, as shown in FIG. 5C, the adhesive 116 is injected into the gap 117. In other embodiments, the adhesive 116 can be deposited generally in the vicinity of and in contact with the spacer 114. Without being bound by theory, it is believed that the spacer 114 can at least restrict the deposited adhesive 116 on the cover 112 to flow via surface tension and/or other attractive mechanisms between the spacer 114 and the adhesive 116. As illustrated in FIG. 5D, the die 111 can then be placed proximate to the cover 112 and in contact with the coupling structure 115. The adhesive 116 can then be cured to secure the die 111, the cover 112, and the spacer 114 together.

The process described above with reference to FIGS. 5A-D can have additional and/or different process stages. For example, the first and second dam portions 114a-b of the spacer 114 can be formed sequentially by depositing, patterning, and etching two separate photoresist layers. Etch-stop or polish-stop layers can also be used when removing a portion of any deposited material.

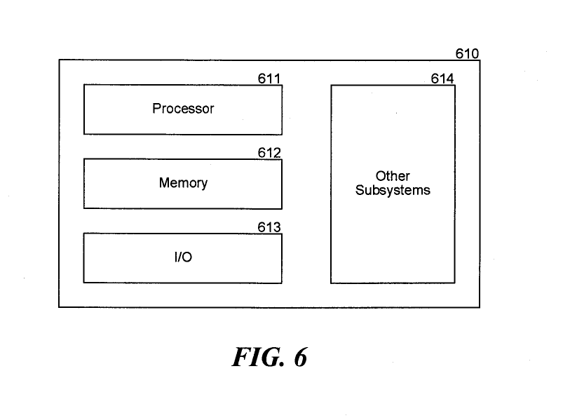

Individual microelectronic imager packages 100 may be incorporated into any of myriad larger and/or more complex systems 610, a representative one of which is shown schematically in FIG. 6. The system 610 can also include a processor 611, a memory 612, input/output devices 613, and/or other subsystems or components 614. The resulting system 610 can perform any of a wide variety of computing, processing, storage, sensor, and/or other functions. Accordingly, the representative system 610 can include, without limitation, computers and/or other data processors, for example, desktop computers, laptop computers, Internet appliances, and hand-held devices (e.g., palm-top computers, wearable computers, cellular or mobile phones, multi-processor systems, processor-based or programmable consumer electronics, network computers, mini computers). The representative system 610 can also include servers and associated server subsystems, display devices, and/or memory devices. Components of the system 610 may be housed in a single unit or distributed over multiple, interconnected units, e.g., through a communications network. Components can accordingly include local and/or remote memory storage devices and any of a wide variety of computer-readable media, including magnetic or optically readable or removable computer disks.

From the foregoing, it will be appreciated that specific embodiments of the disclosure have been described herein for purposes of illustration, but that various modifications may be made without deviating from the disclosure. For example, many of the members of one embodiment may be combined with other embodiments in addition to or in lieu of the members of the other embodiments. Accordingly, the disclosure is not limited except as by the appended claims.

I claim:

1. A microelectronic imager package, comprising:
a semiconductor die having a plurality of photo sensors;
a cover spaced apart from the semiconductor die and facing the photo sensors; and
a coupling structure having a spacer extending from the semiconductor die to the cover and an adhesive contacting the spacer, the semiconductor die, and the cover.

2. The microelectronic imager package of claim 1 wherein the spacer includes a first dam portion and a second dam portion spaced apart from the first dam portion by a gap.

3. The microelectronic imager package of claim 1 wherein the spacer includes a first dam portion and a second dam portion spaced apart from the first dam portion by a gap, and wherein the adhesive is at least partially contained in the gap.

4. The microelectronic imager package of claim 1 wherein the spacer includes a first dam portion and a second dam portion spaced apart from the first dam portion by a gap, and wherein the adhesive is at least partially contained in the gap and extends from the semiconductor die to the cover.

5. The microelectronic imager package of claim 1 wherein the spacer includes a first dam portion and a second dam portion spaced apart from the first dam portion by a gap, and wherein the adhesive is at least partially contained in the gap, and wherein the first and/or second dam portions have a tapered end proximate to the semiconductor die.

6. A system incorporating the microelectronic imager package of claim 1, the system including a processor, a memory, and input/output devices.

7. A microelectronic imager package, comprising:
a semiconductor die having a front side with an image sensor array;
an optical component spaced apart from the image sensor;
a spacer extending around a perimeter of the image sensor array, the spacer comprising a sidewall with a first edge proximate to the optical component and a second edge proximate to the semiconductor die; and
an adhesive in contact with at least a portion of the sidewall of the spacer and having a first end adhered to the semiconductor die and a second end adhered to the optical component.

8. The microelectronic imager package of claim 7 wherein the sidewall is a first sidewall, and wherein the spacer further comprises a second sidewall spaced laterally apart from the first sidewall by a gap, and wherein the adhesive is disposed in the gap between the first and second sidewalls.

9. The microelectronic imager package of claim 7 wherein the optical component is spaced apart from the semiconductor die by a distance, and wherein the sidewall and/or the adhesive has a height at least approximately equal to the distance.

10. The microelectronic imager package of claim 7 wherein the optical component is spaced apart from the semiconductor die by a distance, and wherein the sidewall of the spacer has a first height less than the distance and the adhesive has a second height at least approximately equal to the distance.

11. The microelectronic imager package of claim 7 wherein the spacer includes a unitary spacer and the adhesive is in contact with the spacer along at least a portion of the periphery of the semiconductor die.

12. The microelectronic imager package of claim 11 wherein the spacer includes a plurality of sections arranged in series to form a castlated serpentine-like structure.

13. The microelectronic imager package of claim 11 wherein the spacer includes a plurality of curved sections arranged in series to form a serpentine structure.

14. A microelectronic imager package, comprising:
a semiconductor die having an image sensor array;
a cover spaced apart from a front side of the semiconductor die by a distance;
a channel extending from the cover toward the semiconductor die, the channel being open at the semiconductor die and the cover; and
an adhesive in the channel, wherein the adhesive has a first end adhered to the semiconductor die and a second end adhered to the cover.

15. The microelectronic imager package of claim 14 wherein the channel surrounds at least a portion of the image sensor array.

16. The microelectronic imager package of claim 14 wherein the channel surrounds the image sensor array and has a generally rectangular profile.

17. The microelectronic imager package of claim 14 wherein the channel surrounds the image sensor array and is at least partially non-linear.

18. A method for forming a microelectronic imager package, comprising:
forming a spacer on a cover, the spacer having a first edge proximate to the cover and a second edge extending away from the cover;
disposing an adhesive on the cover, the adhesive being in contact with the spacer and the cover;
placing a semiconductor die proximate to the second edge of the spacer; and
bonding the spacer, the cover, and the semiconductor die together with the adhesive.

19. The method of claim 18 wherein forming a spacer includes
depositing a photoresist layer on the cover;
patterning the photoresist layer deposited on the cover; and
etching the patterned photoresist layer to form a first dam portion and a second dam portion spaced apart from the first dam portion by a gap.

20. The method of claim 19 wherein disposing an adhesive includes injecting the adhesive into the gap between the first and second dam portions.

21. The method of claim 18 wherein forming a spacer includes
depositing a photoresist layer on the cover;
patterning the photoresist layer deposited on the cover; and
etching the patterned photoresist layer to form the spacer that is non-linear along at least a portion of a perimeter of the spacer.

22. The method of claim 18, further comprising at least restricting the deposited adhesive to flow toward a central region of the cover, the central region being radially inward from the peripheral of the cover.

23. A method for forming a microelectronic imager package, comprising:
forming a coupling structure on a cover, the coupling structure including a channel extending away from the cover;
disposing an adhesive into the channel of the coupling structure, the adhesive having a first end proximate to the cover and a second end opposite the first end;
placing a semiconductor die proximate to the second end of the adhesive; and
bonding the semiconductor die to the cover with the adhesive.

24. The method of claim 23 wherein forming a coupling structure includes forming a first sidewall and a second sidewall on the cover, the second sidewall being laterally spaced apart from the first sidewall to form the channel.

25. The method of claim 23 wherein forming a coupling structure includes forming a first sidewall and a second sidewall on the cover, the second sidewall being laterally spaced apart from the first sidewall to form a channel that is non-linear along at least a portion of a perimeter of the spacer.
